(19) United States
(12) Patent Application Publication
(10) Pub. No.: US 2012/0212888 A1
(43) Pub. Date: Aug. 23, 2012

(54) DISPLAY APPARATUS

(75) Inventors: CHI-MING WU, Hsinchu (TW); Jen-Shiun Huang, Hsinchu (TW); Ta-Nien Luan, Hsinchu (TW); Wen-Chang Lu, Hsinchu (TW); Ming-Sheng Chiang, Hsinchu (TW)

(73) Assignee: E Ink Holdings Inc., Hsinchu City (TW)

(21) Appl. No.: 13/156,757

(22) Filed: Jun. 9, 2011

(30) Foreign Application Priority Data
Feb. 18, 2011 (TW) 100105497

(51) Int. Cl. H05K 5/00

(52) U.S. Cl. 361/679.01

(57) ABSTRACT

A display apparatus includes a display panel, at least one anisotropic conductive adhesive and at least one chip. The display panel has a peripheral circuit region, and the anisotropic conductive adhesive is adhered in the peripheral circuit region. The chip is disposed on the anisotropic conductive adhesive, and the chip has an electric coupling region on a surface facing the anisotropic conductive adhesive. The electric coupling region is equipped with a plurality of electric coupling parts, and the electric coupling parts are electrically coupled to the peripheral circuit region by the anisotropic conductive adhesive. An interval is existed between a boundary of the electric coupling region and a boundary of the chip, and the electric coupling region is located in a bonding region of the anisotropic conductive adhesive. The bonding region of the anisotropic conductive adhesive is located in the boundary of the chip. The display apparatus has better reliability.

### FIELD OF THE INVENTION

The present invention relates to a display apparatus, and more particularly to a display apparatus adopting COG (chip on glass) technology.

### BACKGROUND OF THE INVENTION

With the development and progress of flat display technology, the flat display apparatus is getting popular. The earlier flat display apparatus utilizes a rigid substrate as a support substrate and does not have flexibility. For efficiently decreasing weight and thickness of the flat display apparatus, the flexible display apparatus is developed in recent years. Except for the advantages of light weight and thin thickness, the flexible display apparatus is also of flexible and not easily broken. Therefore, the manufacture of the flexible display apparatus has become an important development trend.

FIG. 1 is a schematic view showing a chip adhered in a peripheral circuit region of a display apparatus according to a conventional technique. FIG. 2 is a schematic view showing an anisotropic conductive adhesive of the conventional display apparatus peeled off from a substrate. Referring to FIG. 1, the conventional display apparatus 100 includes a substrate 110, wherein an anisotropic conductive adhesive 120 and a chip 130 are disposed in a peripheral circuit region 112 of the substrate 110. The chip 130 has a plurality of bumps 132, and the bumps 132 are electrically coupled to the peripheral circuit region 112 by the anisotropic conductive adhesive 120. In order to make sure all of the bumps 132 be electrically coupled to the peripheral circuit region 112, a bonding region of the anisotropic conductive adhesive 120 needs to completely cover a bottom surface 131 of the chip 130.

In the conventional technique, the chip 130 is adhered to the peripheral circuit region 112 by a hot head 140 of a hot-pressing equipment. When executing a hot-pressing process, the hot head 140 covers the whole chip 130 for hot-pressing the chip 130 to the anisotropic conductive adhesive 120 and curing the anisotropic conductive adhesive 120. However, because the hot head 140 could not cover a bonding region A1 of the anisotropic conductive adhesive 120 completely, a portion of the anisotropic conductive adhesive 120 beyond a heat region A2 of the hot head 140 may be cured incompletely because of uneven heating. Referring to FIG. 2, the incompletely cured anisotropic conductive adhesive 120 is easily peeled off from the substrate 110. More particularly to the flexible display apparatus, the substrate 110 is a flexible substrate. The incompletely cured anisotropic conductive adhesive 120 may be peeled off from the substrate 110 more easily because of deformation of the flexible substrate, and furthermore, the peripheral circuit will be damaged. Therefore, the conventional display apparatus has poor reliability.

### SUMMARY OF THE INVENTION

The present invention provides a display apparatus with good reliability.

In order to achieve the above-mentioned advantages, the present invention provides a display apparatus including a display panel, at least one anisotropic conductive adhesive and at least one chip. The display panel has a peripheral circuit region, and the anisotropic conductive adhesive is adhered in the peripheral circuit region of the display panel. Besides, the chip is disposed on the anisotropic conductive adhesive, and the chip has a surface facing the anisotropic conductive adhesive and an electric coupling region located on the surface. The electric coupling region is equipped with a plurality of electric coupling parts, and the electric coupling parts are electrically coupled to the peripheral circuit region by the anisotropic conductive adhesive. Moreover, an interval is existed between a boundary of the electric coupling region and a boundary of the chip, and the electric coupling region is located in a bonding region of the anisotropic conductive adhesive. The bonding region of the anisotropic conductive adhesive is located in the boundary of the chip.

In one embodiment of the present invention, the display panel is a bistable display panel, a liquid crystal display panel, an organic light emitting diode display panel, or a plasma display panel.

In one embodiment of the present invention, the display panel includes a substrate, and the peripheral circuit region is formed on the substrate. The substrate is a glass substrate, a plastic substrate or a metal substrate.

In one embodiment of the present invention, the electric coupling parts include a plurality of bumps.

In the display apparatus of the present invention, because the bonding region of the anisotropic conductive adhesive is limited in the boundary of the chip, the anisotropic conductive adhesive could be completely cured when executing a chip mounting process. This could prevent the anisotropic conductive adhesive from being peeled off. Thus, the display apparatus of present invention has better reliability.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic view showing a chip adhered in a peripheral circuit region of a display apparatus according to a conventional technique.

FIG. 2 is a schematic view showing an anisotropic conductive adhesive of the conventional display apparatus peeled off from a substrate.

FIG. 3 is a schematic view of a display apparatus according to an embodiment of the present invention.

FIG. 4 is a schematic view showing a bottom surface of a chip and a spreading region of an anisotropic conductive adhesive of FIG. 3.

FIG. 5 is a schematic view showing a chip adhered in a peripheral circuit region of a display apparatus according to an embodiment of the present invention.

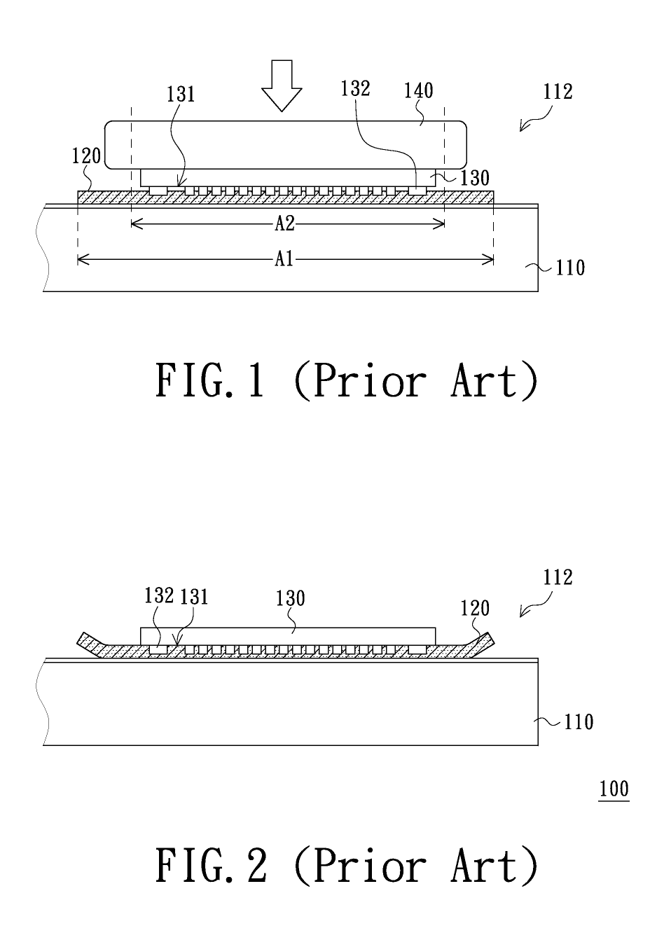

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

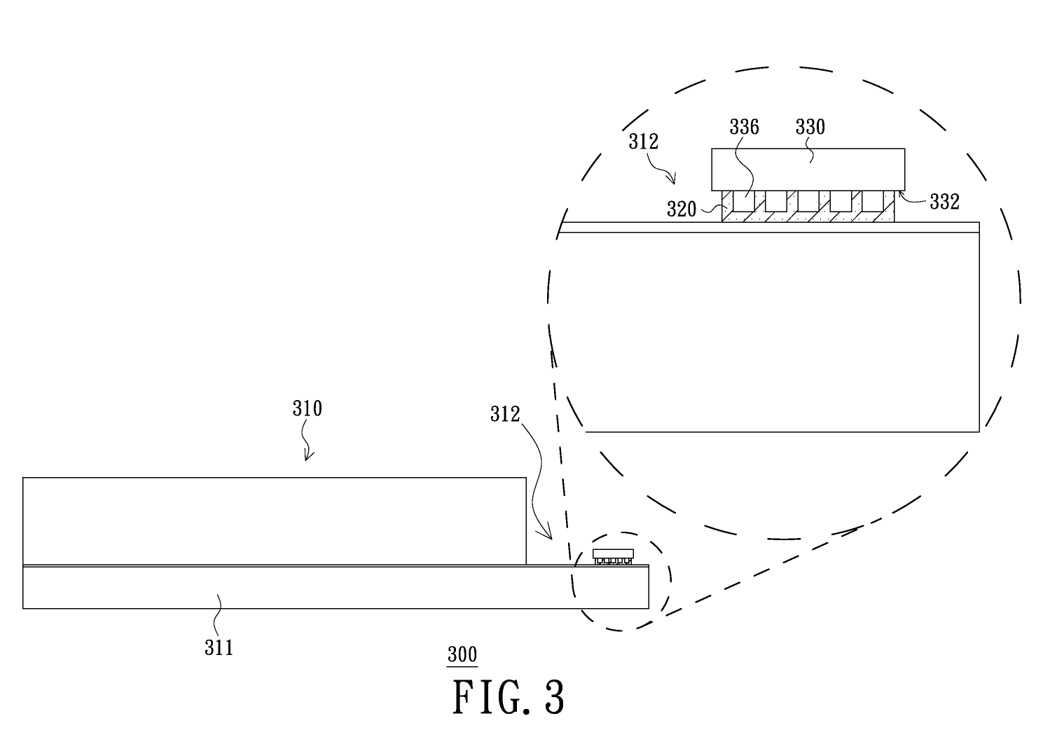

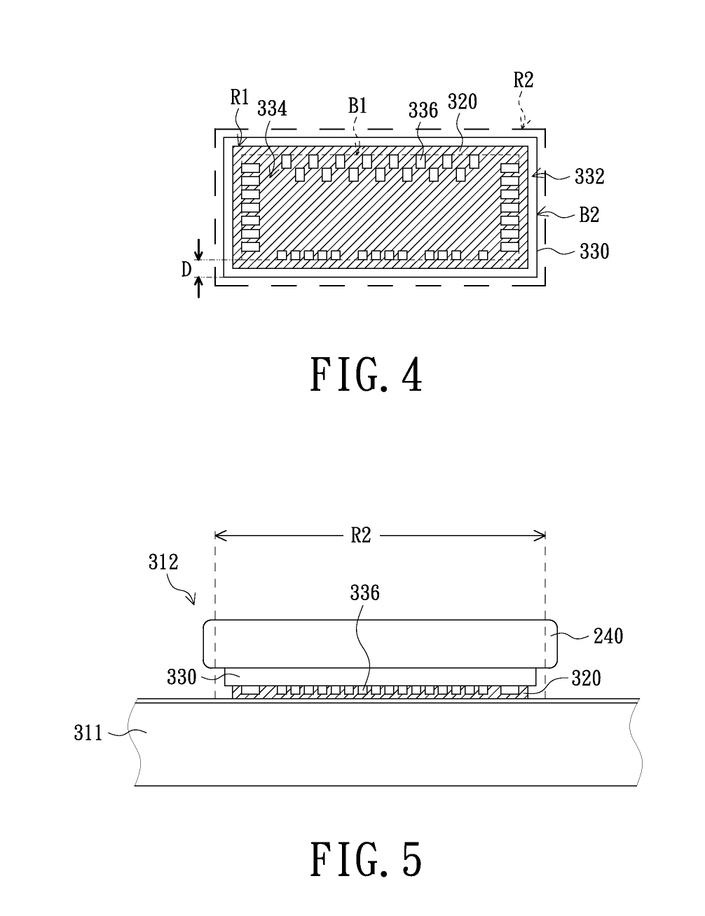

FIG. 3 is a schematic view of a display apparatus according to an embodiment of the present invention. FIG. 4 is a schematic view showing a bottom surface of a chip and a bonding region of an anisotropic conductive adhesive of FIG. 3. Referring to FIGS. 3 and 4, a display apparatus 300 of this embodiment includes a display panel 310, at least one anisotropic conductive adhesive 320 and at least one chip 330. The display panel 310 may be, but not limited to, a bistable display panel, a liquid crystal display panel, an organic light emitting diode display panel, or a plasma display panel. The number of the anisotropic conductive adhesive 320, for example, corresponds to the number of the chip 330, and one anisotropic conductive adhesive 320 and one chip 330 are taken as an example in FIG. 3

The display panel 310 has a peripheral circuit region 312, and the anisotropic conductive adhesive 320 is adhered in the peripheral circuit region 312 of the display panel 310. More concretely, the peripheral circuit region 312 is formed on a substrate 311 of the display panel 310, and the peripheral circuit region 312, for example, is equipped with a plurality of chip bonding pads (not shown) for being electrically connected to the chip 330. The anisotropic conductive adhesive 320 adhered in the peripheral circuit region 312 covers the chip bonding pads. Moreover, the substrate 311 may be a rigid substrate or a flexible substrate, such as a glass substrate, a plastic substrate or a metal substrate. The present invention does not limit the type of the substrate, and a proper substrate will be selected according to design requirement.

The chip 330 is disposed on the anisotropic conductive adhesive 320, and the chip 330 has a surface 332 facing the anisotropic conductive adhesive 320 and an electric coupling region 334 located on the surface 332. The electric coupling region 334 is equipped with a plurality of electric coupling parts 336 corresponding to the chip bonding pads. The electric coupling parts 336 may be bumps and the electric coupling parts 336 are electrically coupled to the chip bonding pads of the peripheral circuit region 312 by the anisotropic conductive adhesive 320.

In this embodiment, the area of the electric coupling region 334 is, for example, the minimized area enclosing all the electric coupling parts 336, and a boundary of the electric coupling region 334 is directed by dash line indicated by B1 of FIG. 4. It should be mentioned that, an interval D is existed between the boundary B1 of the electric coupling region 334 and a boundary B2 of the chip 330. The electric coupling region 334 is located in a bonding region R1 of the anisotropic conductive adhesive 320, and the bonding region R1 of the anisotropic conductive adhesive 320 is located in the boundary B2 of the chip 330. That is to say, the bonding region R1 of the anisotropic conductive adhesive 320 completely covers the electric coupling region 334, and does not extend beyond the boundary B2 of the chip 330.

FIG. 5 is a schematic view showing a chip adhered in a peripheral circuit region of a display apparatus according to an embodiment of the present invention. Referring to FIGS. 4 and 5, in the display apparatus 300 of this embodiment, because the bonding region R1 of the anisotropic conductive adhesive 320 is limited in the boundary B2 of the chip 330, when executing a chip mounting process, a hot head 240 of a hot-press equipment could completely cover the bonding region R1 of the anisotropic conductive adhesive 320. Therefore, all of the anisotropic conductive adhesive 320 is located within a heating region R2 of the hot head 240, thereby preventing the anisotropic conductive adhesive 320 from being cured incompletely. Thus, the display apparatus 300 of this embodiment could eliminate the drawback of the conventional art. That is, the incompletely cured anisotropic conductive adhesive which is easily peeled off is not occurred in the display apparatus 300 of this embodiment. Furthermore, in the display apparatus 300 of this embodiment, a damage of the circuit in the peripheral circuit region 312 caused by the peeling off of the anisotropic conductive adhesive is prevented. Therefore, the display apparatus 300 of this embodiment has better reliability.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A display apparatus, comprising:
a display panel having a peripheral circuit region;
at least one anisotropic conductive adhesive adhered in the peripheral circuit region of the display panel; and
at least one chip disposed on the anisotropic conductive adhesive, and the chip having a surface facing the anisotropic conductive adhesive and an electric coupling region located on the surface, the electric coupling region being equipped with a plurality of electric coupling parts, and the electric coupling parts being electrically coupled to the peripheral circuit region by the anisotropic conductive adhesive, wherein an interval is existed between a boundary of the electric coupling region and a boundary of the chip, the electric coupling region is located in a bonding region of the anisotropic conductive adhesive, and the bonding region of the anisotropic conductive adhesive is located in the boundary of the chip.

2. The reflective display apparatus according to claim 1, wherein the display panel is a bistable display panel, a liquid crystal display panel, an organic light emitting diode display panel, or a plasma display panel.

3. The reflective display apparatus according to claim 1, wherein the display panel includes a substrate, the peripheral circuit region is formed on the substrate, and the substrate is a glass substrate, a plastic substrate or a metal substrate.

4. The reflective display apparatus according to claim 1, wherein the electric coupling parts include a plurality of bumps.
